(19) United States
(12) Patent Application Publication
(10) Pub. No.: US 2022/0009017 A1
(43) Pub. Date: Jan. 13, 2022

(54) SOLDERING NOZZLE, SYSTEM AND USE

(71) Applicant: Illinois Tool Works Inc., Glenview, IL (US)

(72) Inventors: Antonie Cornelis COLIJN, Nieuwendijk (NL); Gerardus Johannes Adrianus Maria DIEPSTRATEN, Dongen (NL)

(21) Appl. No.: 17/350,724

(22) Filed: Jun. 17, 2021

(30) Foreign Application Priority Data
Jul. 8, 2020 (EP) 20184808.2
Apr. 19, 2021 (EP) 21169170.4

(51) Int. Cl. B23K 3/06; B23K 3/08; B23K 1/00

(52) U.S. Cl. CPC B23K 3/0653; B23K 2101/42; B23K 1/0016; B23K 3/08

(57) ABSTRACT

A soldering nozzle for directing solder during a multi-wave soldering operation, the soldering nozzle comprising outlets for solder and de-bridging gas. The solder outlet dispenses solder therefrom and receives a plurality of parts to be soldered. The de-bridging gas outlet directs de-bridging gas between a plurality of soldered parts after they exit the solder outlet. A solder pot comprising a soldering nozzle and a de-bridging gas outlet is further disclosed. The de-bridging gas outlet is arranged relative to the soldering nozzle such that de-bridging gas is directed between a plurality of soldered parts after they exit a solder outlet.

### RELATED APPLICATIONS

The present application claims the benefit of European Patent Application No. 20184808.2, filed Jul. 8, 2020, and to European Patent Application No. 21169170.4, filed Apr. 19, 2021. The entireties of European Patent Application No. 20184808.2 and European Patent Application No. 21169170.4 are incorporated herein by reference.

### FIELD OF THE DISCLOSURE

The present disclosure relates to a soldering nozzle and in particular, but not exclusively, a nozzle for directing a stream of solder during a soldering operation. The present invention also relates to a method of soldering with the nozzle and a soldering system including the nozzle.

### BACKGROUND

Selective soldering can be used in many soldering applications, for example soldering components of a Printed Circuit Board (PCB). Selective soldering can, in general, be differentiated into two methods: multi-wave dip soldering and point-to-point soldering.

In multi-wave dip soldering processes, typically a large solder pot, or soldering assembly 100 is used (as shown in FIG. 1a) having a solder plate 102 that includes nozzles 104 to which liquidus solder is pumped. The soldering assembly 100 is typically closed with a cover plate, which has been removed in FIG. 1a in order to illustrate the nozzles 104 more clearly. FIG. 1a shows that the nozzles 104 are provided in a cavity 108 defined by side walls 110. An upper part of the sidewalls 110 defines a lip 112 on which a cover plate is seated. The cover plate will include openings to expose the nozzles 104. As can be seen in FIG. 1a, the depth of the cavity 108 defined by the height of the sidewalls 110 is selected so that the top of each nozzle 104 will be generally at the same level as the cover plate. The cover plate serves to maintain a low oxygen environment around the nozzles during soldering. The PCB (not shown) is lowered towards the nozzles, such that connector leads/pins (for example in a Cu—Copper—panel) are dipped into the liquidus solder present in the nozzle to form solder connections/joints at corresponding locations on the PCB. That is, multiple solder connections can be formed simultaneously. Each multi-wave dip soldering assembly has a specific nozzle plate with the nozzles being located at the required solder positions. The nozzles may have different shapes depending on the connectors to be soldered and the free space on the assembly. FIG. 1b illustrates a typical nozzle 104 used in a multi-wave dip soldering process. For connectors with a high risk of bridging, a laser-cut screen 106 (provided separately from the nozzle itself) may be provided in the nozzle 104 to help avoid bridging of solder.

In point-to-point soldering processes, typically a small solder pot, or soldering assembly, generally containing only one nozzle, is used. The nozzle comprises a body portion having an inlet at its lower end and an outlet for dispensing liquidus solder. In contrast to multi-wave soldering where the connectors pins are dipped into the nozzle, solder overflows from the outlet and a pin is dragged through or dipped into the flowing solder (or conversely the nozzle may be moved relative to the pin).

As noted above, multi-wave dip soldering processes suffer from the problem of bridging of solder between soldered pins or connectors, or between a soldered pin an another part of the PCB or other apparatus not being soldered. This can cause short circuiting. The known use of a nozzle screen, such as is illustrated in FIG. 1b, provides a partial solution to this bridging, and may thus be referred to as a de-bridging screen. However, such de-bridging screens can be delicate both in manufacture and in use, and are damaged easily (for instance if a pin or other part to be soldered is misaligned). Furthermore, screens (and hence the whole nozzle) must be designed specifically to match a product to be soldered, with holes to match the connectors to be soldered. This requires additional expense and production delay in exchanging nozzles if a solder pot is to be used to soldered different PCBs.

In addition, current methods of manufacturing the soldering components are limited with regards to the nozzle geometry that can be produced. This can lead to sub-optimal nozzles. The trend in the industry is that components are getting smaller. This miniaturization result in a smaller pitch between the pins. For pitches smaller than 2.00 mm it is not physically possible to make a screen because the distance has become too small, owing to it not being feasible to laser cut screens with smaller than 0.3 mm dimensions. It is a known problem of screens that flux residue from a PCB can clog a screen with small holes. During cleaning the screen may be damaged owing to its fragility. For these small pitches another de-bridging technology is required.

As used herein, when referring to ‘solder’ in use within a nozzle, it is to be understood that the solder is in a liquid state.

It would be advantageous to produce a soldering system that helps overcome the above described problems. Particularly, it would be advantageous to reduce occurrences of bridging during multi-wave dip soldering processes. It would be advantageous to provide a nozzle for multi-wave dip soldering processes that is more robust, less fragile and less sensitive for contamination and clogging. It would be advantageous to provide a nozzle for multi-wave dip soldering processes that is better able to accommodate different pins or components to be soldered.

### SUMMARY

According to a first aspect of the present disclosure there is provided a soldering nozzle for directing solder during a multi-wave soldering operation, the soldering nozzle comprising: a solder outlet for dispensing solder therefrom and to receive a plurality of parts to be soldered; and a de-bridging gas outlet arranged to direct de-bridging gas between a plurality of soldered parts after they exit the solder outlet.

According to a second aspect of the present disclosure there is provided a solder pot comprising: a solder plate; and at least one nozzle as described above, the at least one nozzle being provided on the solder plate such that liquidus solder and de-bridging gas can be supplied to the nozzle.

According to a third aspect of the present disclosure there is provided a solder pot comprising: a soldering nozzle for directing solder during a multi-wave soldering operation, the soldering nozzle comprising a solder outlet for dispensing solder therefrom and to receive a plurality of parts to be soldered; and a de-bridging gas outlet located relative to the soldering nozzle such that de-bridging gas is directed between a plurality of soldered parts after they exit the solder outlet.

According to a fourth aspect of the present disclosure there is provided a system for soldering a component, comprising: a supply of liquid solder; a solder pot as described above; and a pump configured to pump solder from the solder supply to the at least one nozzle of the soldering assembly.

According to a fifth aspect of the present disclosure there is provided the use of a soldering pot in a multi-wave soldering operation, the soldering pot comprising a nozzle including a solder outlet for dispensing solder therefrom and a de-bridging gas outlet arranged to direct de-bridging gas between a plurality of soldered parts after they exit the solder outlet.

For the avoidance of doubt, any of the features described herein apply equally to any aspect of the disclosure.

### BRIEF DESCRIPTION OF THE DRAWINGS

Embodiments of the disclosure are further described hereinafter with reference to the accompanying drawings, in which:

FIGS. 1a and 1b illustrates a perspective view of a solder pot and a nozzle (respectively) for use in multi-wave dip soldering processes;

FIG. 2 illustrates a perspective view of a nozzle in accordance with an example of the present disclosure for use in multi-wave dip soldering processes;

FIG. 3a illustrates an apparatus for transporting a PCB to a solder pot;

FIG. 3b illustrates the apparatus of FIG. 3a performing multi-wave dip soldering;

FIG. 4 illustrates a perspective view of a nozzle in accordance with another example of the present disclosure for use in multi-wave dip soldering processes;

FIG. 5 illustrates a solder pot cover plate including an opening for a nozzle and a de-bridging gas outlet in accordance with a further example of the present disclosure; and

FIG. 6 shows in detail the de-bridging gas outlet of FIG. 5, mounted upon a cover plate.

In the drawings like reference numerals refer to like parts.

### DETAILED DESCRIPTION

In its most general form, a soldering assembly is disclosed including at least one nozzle for directing solder during a soldering operation. The soldering assembly may be a soldering assembly for use in multi-wave soldering process (typically including more than one nozzle).

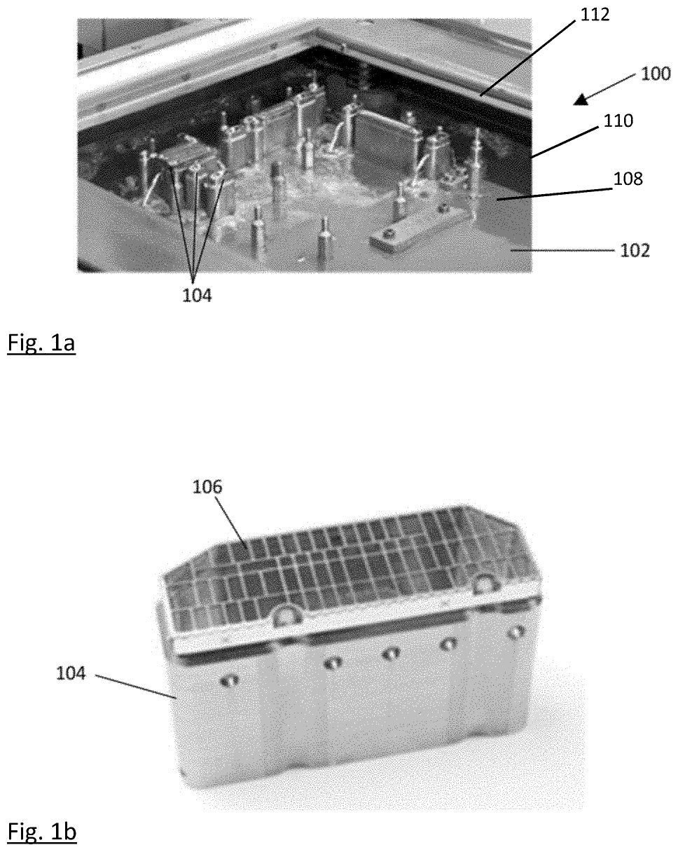

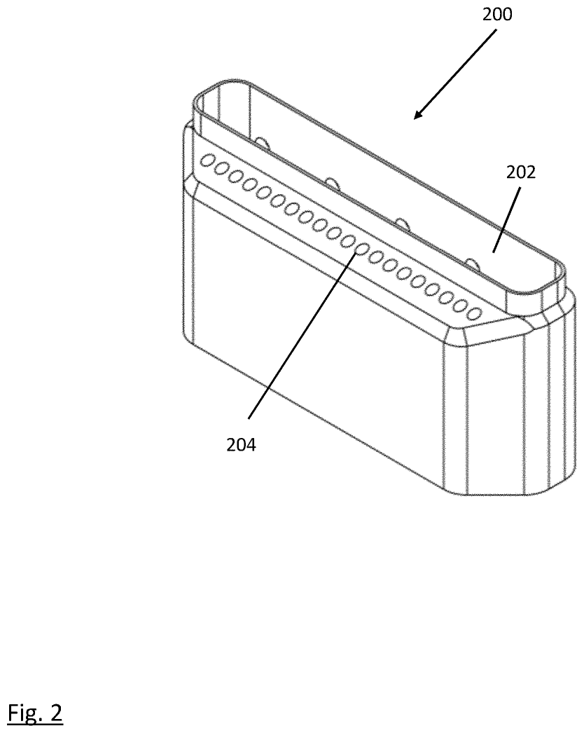

Referring to FIG. 2, this illustrates a soldering nozzle 200 according to an example of the present disclosure for directing solder during a multi-wave soldering operation. The nozzle 200 comprises a solder outlet 202 to which solder may be pumped. PCB leads, connectors, or other components to be soldered may be dipped into the solder outlet 202, as is conventional for a multi-wave soldering process, and in this respect nozzle 200 may be functionally the same as nozzle 104 illustrated in FIG. 1a. However, in accordance with an example of the present disclosure, nozzle 200 further comprises at least one de-bridging gas outlet 204. FIG. 2 illustrates an example in where a plurality of de-bridging gas outlets 204 are arranged along one side of the solder outlet 202. After parts to be soldered are dipped into solder within the solder outlet 202 and then exit the solder outlet, the or each de-bridging gas outlet 204 is arranged to direct de-bridging gas between the soldered parts to remove solder in unwanted locations between the soldered parts, where otherwise there would be a risk of solder bridges forming.

The de-bridging gas may comprise nitrogen blown between soldered parts or leads to remove the solder when it is still liquidus. Other inert gases may also be used, and suitable inert de-bridging gases will be known to the skilled person. Other gases such as carbon dioxide may be suitable in some situations. The de-bridging gas may be heated to above the solder liquidus temperature. In some situations heating may not be required if solder adhering to the PCB is expected to remain above the liquidus temperature for long enough. After the PCB of other part being soldered is dipped in the solder, the de-bridging gas is blown underneath the board.

As de-bridging is performed by blowing de-bridging gas towards a PCB after parts to be soldered have been dipped in the solder outlet, there is no requirement for a screen across the solder outlet to perform de-bridging. The de-bridging gas may be blown continuously (at least during a particular soldering operation). In some alternatives, the de-bridging gas may be jetted intermittently when the PCB is located relative to the gas outlets 204 such that a location for which de-bridging is required is presented to a gas outlet 204. In some examples each of a plurality of gas outlets may be blowing de-bridging gas at the same time, or they may be separately controlled.

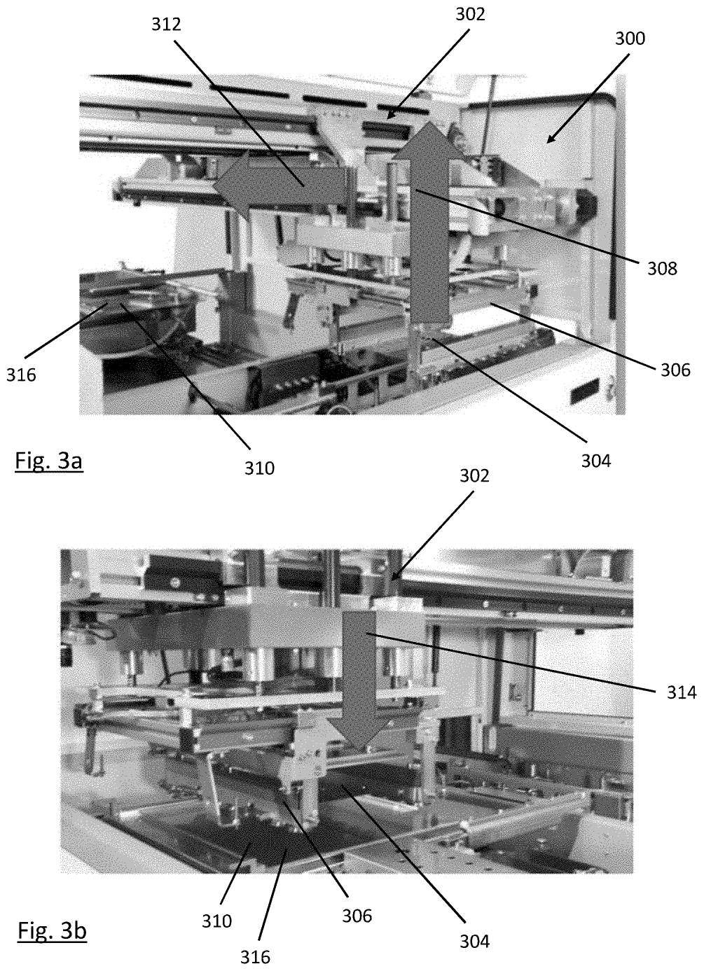

Referring now to FIGS. 3a and 3b a soldering system 300 suitable for implementing multi-wave soldering including a nozzle according to FIG. 2 will be described. Other than the nozzle, the soldering system 300 may be similar to conventional multi-wave soldering processes. The soldering system 300 comprises a robot 302 (also referred to as an actuating means or translation means) arranged to pick up a PCB 304 from a conveyor, lift the PCB 304 into a shuttle 306 in the direction of arrow 308. The shuttle 306 then moves the PCB 304 to solder pot 310 in the direction of arrow 312. In FIGS. 3a and 3b a cover plate 316 is visible which as described above closes off the top of the solder pot 310 except for openings where one or more nozzles are exposed (not clearly visible in FIGS. 3a and 3b) in order to maintain a low oxygen environment during soldering.

The shuttle 306 then aligns the PCB 304 with solder pot 310 (and nozzle 200, though not visible in FIGS. 3a and 3b) and lowers parts to be soldered into solder outlet 202 in the direction of arrow 314. The shuttle 306 then lifts the PCB 304 such that it clears the solder outlet 202. The de-bridging gas outlets 204 direct the de-bridging gas between the solder parts to prevent solder bridges forming. As noted above, the de-bridging gas outlets 204 may be continuously blowing de-bridging gas. As the shuttle 306 lifts the PCB 304 clear of the solder outlet 202, the solder parts move into the gas flow from outlets 204 such that de-bridging occurs. In some examples, after the PCB 304 is clear of the solder outlet 202 is may be transferred by the robot 302 such that the solder parts move through the gas flow.

FIG. 2 illustrates an example of a nozzle 200 in which there is an array of de-bridging gas outlets located along one long side of a generally rectangular solder outlet. However it will be appreciated that this may vary. Firstly, the shape of the solder outlet may be dictated mainly by the shape and disposition of parts to be soldered in a multi-wave soldering process. Secondly, there may be only a single de-bridging gas outlet, or if there is a plurality then they may be arranged differently, for instance being provided on two sides of the solder outlet. In one example the de-bridging gas outlets are arranged on a downstream side of the nozzle, in the sense that after parts to be soldered are dipped into the solder outlet and then removed, they pass over the de-bridging gas outlets as they are transported out of the solder pot.

The flow rate, direction and temperature of the de-bridging gas defines if a bridge will be removed or not. Typically, the de-bridging gas is blown in between two leads. A flow rate will be configured to remove the solder bridge, and the flow rate may depend on the pitch between leads. For instance, to remove a bridge the flow rate may be 2-10 litres/minute. The flow rate may be proportional to the size of the nozzle, and in particular the size of the or each gas outlet 204. The gas temperature may be well above the melting point of the solder. However, in some examples the solder is expected to remain above the solder liquidus temperature at the time it is exposed to the de-bridging gas flow and so lower temperature gases may be used. Furthermore, where an array of de-bridging gas outlets are provided, it may be that all operate simultaneously to jet de-bridging gas towards a PCB to remove solder bridges across the whole PCB. Alternatively, in some examples the de-bridging gas outlets may be separately controlled to adjust or stop the flow of de-bridging gas.

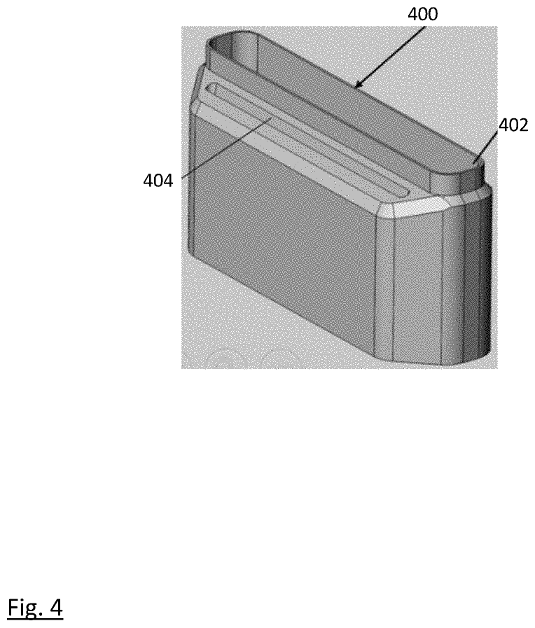

Referring now to FIG. 4, this illustrates a soldering nozzle 400 according to another example of the present disclosure for directing solder during a multi-wave soldering operation. The nozzle 400 is similar to the nozzle 200 illustrated in FIG. 2, and comprises a solder outlet 402 to which solder may be pumped. However, in place of an array of de-bridging gas outlets, a single elongate orifice 404 is provided, which acts as an air knife to direct a continuous jet of de-bridging gas across some or all of the width of the solder outlet 402. Other variations will be apparent to the skilled person, for instance an air knife broken into two or more sections or a combination of an array orifices with an air knife linearly arranged along a nozzle. In further examples it may be that a sequential (in the direction of PCB movement) series of de-bridging orifices or slots may be provided.

The nozzle incorporating the de-bridging gas outlets may be integrally formed. Suitably, it may be manufactured by 3D printing the nozzle. However, the present disclosure is not limited to the use of 3D printing. This makes it possible that provide substantially any required shape to define the channels for solder and de-bridging gas within the body of the nozzle itself. The nozzle will have a connection (nipple or threaded tube) to connect tubing for de-bridging gas supply, as well as a connection to a source of solder.

To 3D print the nozzle, the nozzle may include a plurality of stacked layers, for instance of stainless steel or titanium, provided so as to at least partially define the required channels. In this example, the stacked layers are deposited during an additive manufacturing, or 3D printing, process. That is, during construction, successive layers of stainless steel or titanium are deposited to build up the nozzle structure.

As an example of an additive manufacturing or 3D printing process, a thin layer (for example, of 20 to 100 microns thickness) of metal powder (for example stainless steel or titanium) is laid down on top of a build-plate. The powder is melted or welded together in predetermined positions, for example by a laser or welding means. The predetermined positions may be defined by a 3D CAD model, for example. The build-plate is lowered by a distance substantially corresponding to the thickness of the thin layer and these steps are repeated. Once the required number of layers have been added, the non-melted/welded powder is removed to reveal the component inside. The component may be heat treated to improve the mechanical properties or post-processed (for example turning, milling, tumbling or shot peening).

The construction of a nozzle in this way allows different shapes and models to be produced that would generally not be possible with milling, drilling or casting processes. As such, nozzles with improved functionality may be produced. In addition, the use of materials within the printed nozzles may be more efficient.

Previously, it would have been expected that a 3D printed component, such as the nozzle of this disclosure, would have a rough surface (as a result of the addition of successive layers). As such, there would be an expectation that the roughened surface of the nozzle (in particular, the surface defining the channel) may affect the nozzles ability to produce a consistent, laminar flow of solder. However, surprisingly, this has found to not be an issue for the 3D printed nozzle.

In a further example, the entire solder pot assembly may be 3D printed. That is, the solder pot may include a plurality of stacked layers of stainless steel or titanium.

The multi-wave soldering nozzles of FIGS. 2 and 4 incorporate an integral de-bridging gas outlet, which may for instance be suitably formed through 3D printing the nozzle. However, according to the present disclosure it is not essential that the de-bridging gas outlet is integrally formed with the solder nozzle, only that it be provided proximal to the nozzle at a location such that when the soldered parts of the PCB are lifted clear of the solder outlet (or as the PCB is moved downstream), de-bridging gas is blown across the solder parts to perform de-bridging. Suitably this may be achieved by providing a de-bridging gas outlet (which may be referred to as an air-knife) to a cover plate, at or close to an opening for a nozzle. However, the de-bridging gas outlet may be supported or positioned independently of the cover plate. The de-bridging gas outlet may be fixed in position relative to the solder nozzle.

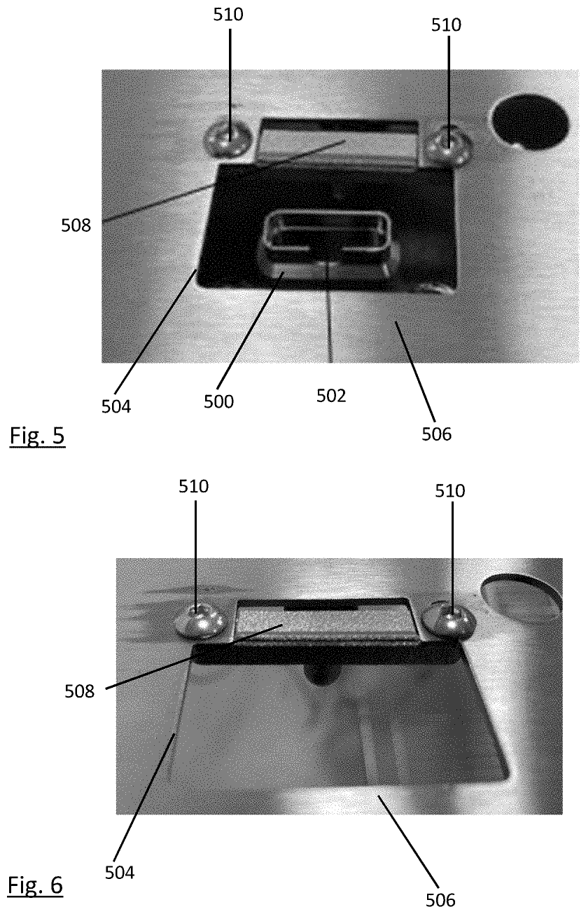

Referring now to FIGS. 5 and 6, these illustrate a portion of a solder pot in accordance with a further example of the present disclosure in which a cover plate includes an opening for a nozzle and a de-bridging gas outlet. Solder nozzle 500 is shown, including solder outlet 502. As the nozzle 500 does not incorporate a de-bridging gas outlet, it may be generally similar to nozzle 104 of FIG. 1b, though no screen 106 is required. Nozzle 500, and particularly solder outlet 502, is shown exposed within opening 504 of cover plate 506. Cover plate 506 closes off the solder pot cavity as described above in connection with FIG. 1a, though only the portion surrounding opening 504 is shown in FIGS. 5 and 6. It will be appreciated that cover plate 506 may include further openings associated with further nozzles.

FIGS. 5 and 6 further show a de-bridging gas outlet 508 in the form of an air knife with a single elongate gas outlet. It will be appreciated that alternatively two or more discrete gas openings may be provided. In the example of FIGS. 5 and 6 the de-bridging gas outlet 508 is 3D printed and secured to the cover plate 506 with screws 510. However, it will be appreciated firstly that 3D printing is only one suitable fabrication technique and secondly that alternative fixation techniques will be well known to the skilled person. Indeed, in some examples the de-bridging gas outlet 508 may be integrally formed with the cover plate 506 itself. It can be seen that the de-bridging gas outlet 508 is directed towards the solder outlet 502 so that gas will be blown across parts of the PCB as they are lifted clear of the solder outlet 502, or moved downstream from the solder outlet 502 over the de-bridging gas outlet 508.

It will be clear to a person skilled in the art that features described in relation to any of the embodiments described above can be applicable interchangeably between the different embodiments. The embodiments described above are examples to illustrate various features of the disclosure.

For the avoidance of doubt, the terms “may”, “and/or”, “e.g.”, “for example” and any similar term as used herein should be interpreted as non-limiting such that any feature so described need not be present. Indeed, any combination of optional features is expressly envisaged without departing from the scope of the disclosure, whether or not these are expressly claimed. The applicant reserves the right to change any originally filed claim or file any new claim, accordingly, including the right to amend any originally filed claim to depend from and/or incorporate any feature of any other claim although not originally claimed in that manner.

Throughout the description and claims of this specification, the words “comprise” and “contain” and variations of them mean “including but not limited to”, and they are not intended to (and do not) exclude other components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

It will be appreciated by those skilled in the art that several variations to the aforementioned embodiments are envisaged without departing from the scope of the disclosure. It will also be appreciated by those skilled in the art that any number of combinations of the aforementioned features and/or those shown in the appended drawings provide clear advantages over the prior art and are therefore within the scope of the disclosure described herein.

The reader's attention is directed to all papers and documents which are filed concurrently with or previous to this specification in connection with this application and which are open to public inspection with this specification, and the contents of all such papers and documents are incorporated herein by reference.

What is claimed is:

1. A soldering nozzle for directing solder during a multi-wave soldering operation, the soldering nozzle comprising:
a solder outlet for dispensing solder therefrom and to receive a plurality of parts to be soldered; and
a de-bridging gas outlet arranged to direct de-bridging gas between a plurality of soldered parts after they exit the solder outlet.

2. A soldering nozzle according to claim 1, further comprising:
a solder channel having a solder inlet for receiving a supply of solder and the solder outlet for dispensing solder therefrom; and
a de-bridging gas channel having a de-bridging gas inlet and the de-bridging gas outlet.

3. A soldering nozzle according to claim 1, wherein the solder outlet and the de-bridging gas outlet are integrally formed.

4. A soldering nozzle according to claim 1, wherein the nozzle comprises a plurality of de-bridging gas outlets arranged relative to the solder outlet such that de-bridging gas is directed between the plurality of soldered parts to remove solder bridging after the soldered parts exit the solder outlet.

5. A soldering nozzle according to claim 4, wherein the plurality of de-bridging gas outlets are arranged along a first side of the solder outlet.

6. A solder pot comprising:
a solder plate; and
at least one nozzle according to claim 1, the at least one nozzle being provided on the solder plate such that liquidus solder and de-bridging gas can be supplied to the nozzle.

7. A solder pot comprising:
a soldering nozzle for directing solder during a multi-wave soldering operation, the soldering nozzle comprising a solder outlet for dispensing solder therefrom and to receive a plurality of parts to be soldered; and
a de-bridging gas outlet located relative to the soldering nozzle such that de-bridging gas is directed between a plurality of soldered parts after they exit the solder outlet.

8. The solder pot of claim 7, where the soldering nozzle and the de-bridging gas outlet are arranged in a fixed spatial arrangement.

9. The solder pot of claim 7, further comprising a cover plate, wherein the cover plate incorporates at opening to expose the solder outlet, and wherein the de-bridging gas outlet is coupled to or incorporated into the cover plate.

10. The solder pot of claim 9, wherein the de-bridging gas outlet is provided at or proximal to an edge of the opening.

11. The solder pot of claim 7, wherein the at least one soldering nozzle is provided on a solder plate such that liquidus solder and de-bridging gas can be supplied to the nozzle

12. A system for soldering a component, comprising
a supply of liquidus solder;
a solder pot according to claim 7; and
a pump configured to pump solder from the solder supply to the at least one nozzle of the soldering assembly.

13. A system according to claim 12, further comprising:
a supply of de-bridging gas coupled to the de-bridging gas outlet.

14. A method to use a solder pot in a multi-wave soldering operation, the method comprising:
dispensing solder from a solder outlet of a nozzle, and
directing de-bridging gas from a de-bridging gas outlet arranged to between a plurality of soldered parts after they exit the solder outlet.
